(19) United States
(12) Patent Application Publication
(10) Pub. No.: US 2014/0002991 A1
(43) Pub. Date: Jan. 2, 2014

(54) THERMAL MANAGEMENT IN OPTICAL AND ELECTRONIC DEVICES

(71) Applicants: Rajdeep Sharma, Sunnyvale, CA (US); Stanton Earl Weaver, JR., Broadalbin, NY (US); Mehmet Arik, Cekmekoy (TR)

(72) Inventors: Rajdeep Sharma, Sunnyvale, CA (US); Stanton Earl Weaver, JR., Broadalbin, NY (US); Mehmet Arik, Cekmekoy (TR)

(73) Assignee: GENERAL ELECTRIC COMPANY, Schenectady, NY (US)

(21) Appl. No.: 13/538,768

(22) Filed: Jun. 29, 2012

(51) Int. Cl. H05K 7/20; F28D 15/00

(52) U.S. Cl. 361/694; 165/104.34

(57) ABSTRACT

A thermal management system for electronic devices is provided. The thermal management system includes one or more synthetic jets. The synthetic jets may be used to facilitate airflow in the thermal management system, such as to facilitate air flow over a heat sink in one implementation. In one implementation, the synthetic jets are operated at an ultrasonic frequency.

### BACKGROUND

The present disclosure relates generally to thermal management and heat transfer, and more particularly to thermal management in optical and electronic devices.

High efficiency lighting systems are continually being developed to compete with traditional area lighting sources, such as incandescent or florescent lighting. While light emitting diodes (LEDs) have traditionally been implemented in signage applications, advances in LED technology have fueled interest in using such technology in general area lighting applications. LEDs and organic LEDs are solid-state semiconductor devices that convert electrical energy into light. While LEDs implement inorganic semiconductor layers to convert electrical energy into light, organic LEDs (OLEDs) implement organic semiconductor layers to convert electrical energy into light. Significant developments have been made in providing general area lighting implementing LEDs and OLEDs.

One potential drawback in LED applications is that during usage, a significant portion of the electricity in the LEDs is converted into heat, rather than light. If the heat is not effectively removed from an LED lighting system, the LEDs will run at high temperatures, thereby lowering the efficiency and reducing the reliability of the LED lighting system. In order to utilize LEDs in general area lighting applications where a desired brightness is required, thermal management systems to actively cool the LEDs may be considered. Providing an LED-based general area lighting system that is compact, lightweight, efficient, reliable, and bright enough for general area lighting applications is challenging. While introducing a thermal management system to control the heat generated by the LEDs may be beneficial, the thermal management system itself also introduces a number of additional design challenges.

### BRIEF DESCRIPTION

In one embodiment, a synthetic jet assembly is provided. The synthetic jet assembly comprises a spacer comprising at least one opening through which air flows when the synthetic jet assembly is operated and a pair of synthetic jet diaphragms attached to opposite sides of the spacer. Each synthetic jet diaphragm comprises a deformable shim and a piezoelectric element attached to the deformable shim. The synthetic jet assembly also comprises control circuitry configured to drive the pair of synthetic jet diaphragms at an ultrasonic frequency.

In another embodiment, an electronic device is provided. The electronic device comprises one or more heat generating electrical components and a thermal management system. The thermal management system comprises a heat sink in thermal communication with the one or more heat generating electrical components and one or more synthetic jets. Each synthetic jet comprises a pair of synthetic jets diaphragms and a spacer positioned between each pair of synthetic jet diaphragms. Each pair of synthetic jet diaphragms is separated by a spacer. Each spacer comprises an opening through which air is expelled toward the heat sink during operation of the synthetic jet diaphragms. The electronic device further comprises a control circuit in communication with the one or more synthetic jets. The control circuit is configured to drive each synthetic jet at an ultrasonic frequency.

In another embodiment, a method for cooling an electronic device is provided. The method comprises driving a synthetic jet at an ultrasonic frequency such that air is expelled from the synthetic jet over a heat sink in thermal communication with a heat generating component.

### BRIEF DESCRIPTION OF THE DRAWINGS

These and other features, aspects, and advantages of the present invention will become better understood when the following detailed description is read with reference to the accompanying drawings in which like characters represent like parts throughout the drawings, wherein:

FIG. 1 is block diagram of a lighting system in accordance with aspects of the present disclosure;

FIG. 2 illustrates a perspective view of a lighting system, in accordance with aspects of the present disclosure;

FIG. 3 illustrates an exploded view of the lighting system of FIG. 2, in accordance with aspects of the present disclosure;

FIG. 4 illustrates another exploded view of the lighting system of FIG. 2, in accordance with aspects of the present disclosure;

FIG. 5 depicts a view of an additional lighting system, in accordance with aspects of the present disclosure;

FIG. 6 depicts an exploded and sectional view of the base of the lighting system of FIG. 6, in accordance with aspects of the present disclosure;

FIG. 7 depicts an exploded view of components of a synthetic jet, in accordance with aspects of the present disclosure;

FIG. 8 depicts a side view of a diaphragm of a synthetic jet, in accordance with aspects of the present disclosure;

FIG. 9 depicts a plan view of a diaphragm of a synthetic jet, in accordance with aspects of the present disclosure;

FIG. 10 depicts an axi-symmetric layer view of one embodiment of a diaphragm of a synthetic jet, in accordance with aspects of the present disclosure; and

FIG. 11 depicts an axi-symmetric layer view of another embodiment of a diaphragm of a synthetic jet, in accordance with aspects of the present disclosure.

### DETAILED DESCRIPTION

Aspects of the present disclosure relate generally to LED-based area lighting systems or to other electronic and/or optical devices that utilize, or would benefit from, thermal management (e.g., cooling or other types of heat transfer). For example, in one implementation, a lighting system is provided with driver electronics, LED light source(s), and an active cooling system (i.e., a thermal management system), which includes synthetic jets arranged and secured into the system in a manner which optimizes actuation of the synthetic jets and air flow through the thermal management system, thereby providing a more efficient lighting system. The thermal management system includes synthetic jets used to provide an air flow in and out of the lighting system, thereby cooling the lighting system when in operation. As discussed herein, the synthetic jets are operated in such a manner as to generate little or no perceptible noise.

In one embodiment, a lighting system uses a conventional screw-in base (i.e., Edison base) that is connected to the electrical grid. The electrical power is appropriately supplied to the thermal management system and to the light source by the same driver electronics unit. In certain embodiments, synthetic jet devices are provided to work in conjunction with a heat sink having a plurality of fins, and air ports, to both actively and passively cool the LEDs. In one such embodiment, the synthetic jets are arranged to provide air flow across fins of a heat sink and are operated at a frequency that is outside the range of typical human perception. As will be described, the synthetic jet devices are operated at a power level sufficient to provide adequate cooling during illumination of the LEDs.

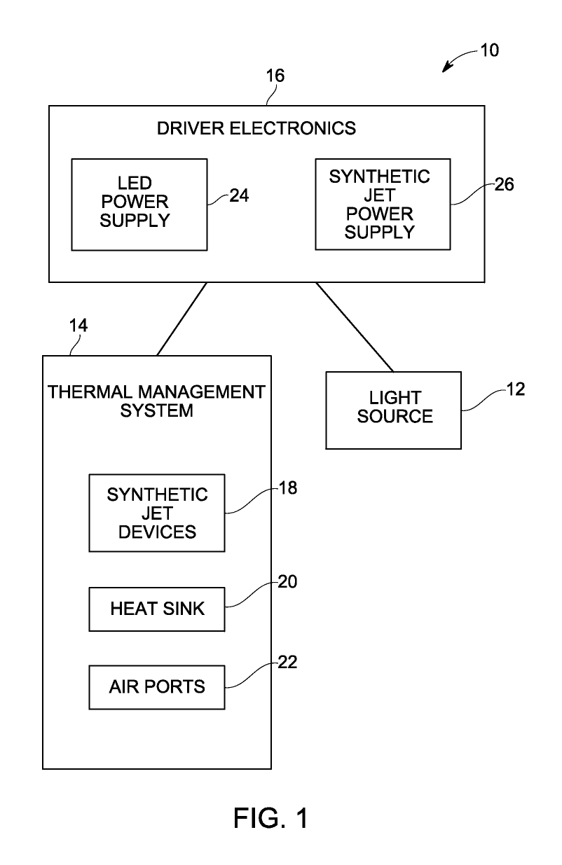

Referring now to FIG. 1, a block diagram illustrates an example of an electrical system to be cooled in the form of a lighting system 10. In one embodiment, the lighting system 10 may be a high-efficiency solid-state down-light luminaire or other form of general purpose lighting. In general, the lighting system 10 includes a light source 12, a thermal management system 14, and driver electronics 16 configured to drive each of the light source 12 and the thermal management system 14. As discussed further below, the light source 12 includes a number of LEDs arranged to provide down-light illumination suitable for general area lighting. In one embodiment, the light source 12 may be capable of producing at least approximately 1500 face lumens at 75 lm/W, CRI>80, CCT=2700k-3200k, 50,000 hour lifetime at a 100° C. LED junction temperature. Further, the light source 12 may include color sensing and feedback, as well as being angle controlled.

As will also be described further below, the thermal management system 14 is configured to cool the heat generating electronics (such as the LEDs in this example) when in operation. In one embodiment, the thermal management system 14 includes synthetic jet devices 18, heat sinks 20 and air ports (i.e., ventilation slots or holes 22) to provide the desired cooling and air exchange for the lighting system 10. As will be described further below, the synthetic jet devices 18 are arranged and secured in an arrangement that provides the desired level of air flow for cooling and are operated at an ultrasonic frequency outside the typical range of sound perception.

The driver electronics 16 include an LED power supply 24 and a synthetic jet power supply 26. In accordance with one embodiment, the LED power supply 24 and the synthetic jet power supply 26 each comprise a number of chips and integrated circuits residing on the same system board, such as a printed circuit board (PCB), wherein the system board for the driver electronics 16 is configured to drive the light source 12, as well as the thermal management system 14. By utilizing the same system board for both the LED power supply 24 and the synthetic jet power supply 26, the size of the lighting system 10 may be reduced or minimized. In an alternate embodiment, the LED power supply 24 and the synthetic jet power supply 26 may each be distributed on independent boards.

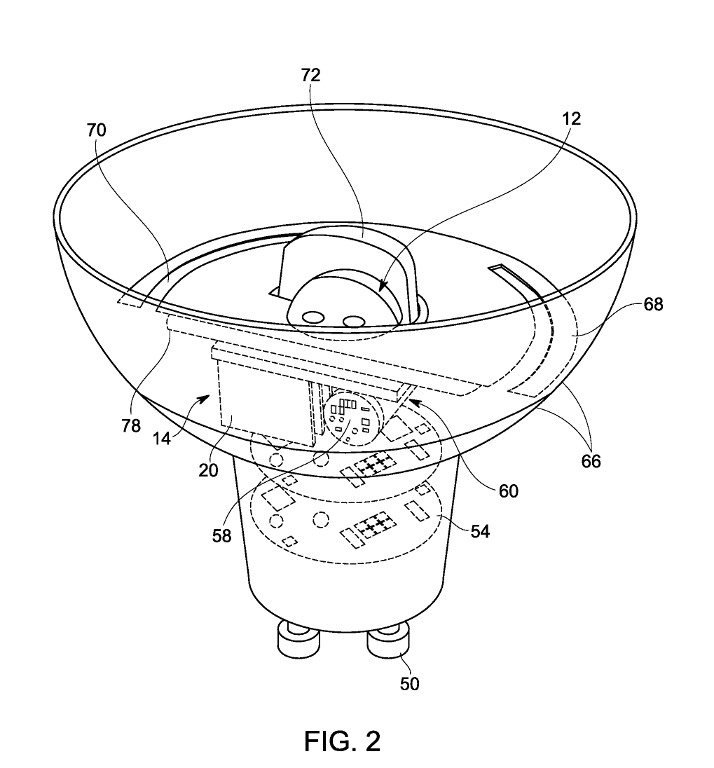

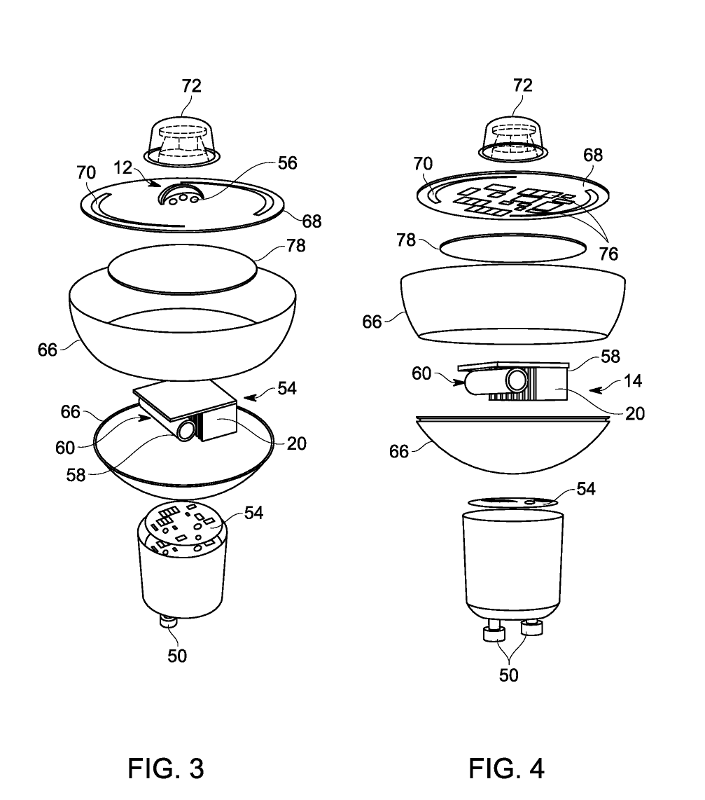

Referring now to FIGS. 2-4, FIG. 2 depicts a partial cut-away view of one embodiment of a lighting system 10 (here depicted as a bulb) incorporating a thermal management system as discussed herein. Further, FIGS. 3 and 4 depict perspective, exploded views of the lighting system 10 as depicted in FIG. 2. Turning to the figures, in the depicted example, electrical prongs or contacts 50 are depicted which may be used to connect the lighting system 10 to a powered fixture or socket or to otherwise connect the lighting system to a source of electricity. Lamp electronics 54 are also provided that, when in operation may drive or otherwise control operation of the light elements, e.g., LEDs 56. In certain embodiments, the lamp electronics may also drive or otherwise control operation of the thermal management system 14, though in the depicted example, separate thermal management electronics 58 (e.g., synthetic jet driver electronics) are provided for controlling operation of the thermal management system 14.

In the depicted example, the thermal management system 14 includes an assembly 60 of synthetic jet devices 18, as discussed in greater detail below. In addition, the thermal management system 14 includes a heat sink 20, which may include multiple cooling fins 62 (FIG. 4). In the depicted example, the driver electronics 58 control operation of the synthetic jet devices 18 to facilitate air flow over the heat sink 20.

The depicted lighting system 10 also includes various housing structures 66 that house the respective lamp and thermal management electronics 54, 58, the thermal management system 14, and the light source 12 and associated lighting structures or optics 72. In certain embodiments, the housing structure 66 may include reflective surfaces that help direct light generated by the light source 12. In addition, the housing structures 66 may support or encompass a substrate or board 68 on which the light generating components (e.g., LEDs 56) are provided. In the depicted example, the board 68 includes ventilation slots 22 that allow the passage of air to and from the thermal management system 14 and the surrounding environment. As will be appreciated, in other embodiments, ventilation may be provided at different locations (such as in one or more components of the housing structure) and/or in different forms or shapes (such as in the form of holes or other passages as opposed to slots).

In the depicted example, the board 68 on which the LED's are incorporated includes electronics 76 on the face of the board opposite the light emitting portions of the LEDs 56. The heat associated by these LED electronics 76 during operation may be conducted, such as via a thermally conductive compression pad 78, to the heat sink 20. In operation, heat from the operation of the LED's 56 may be conducted to the heat sink 20. The synthetic jets 18 may then be used to conduct air around fins of the heat sink 20, thereby dissipating the heat conducted to the heat sink 20 into the surrounding environment.

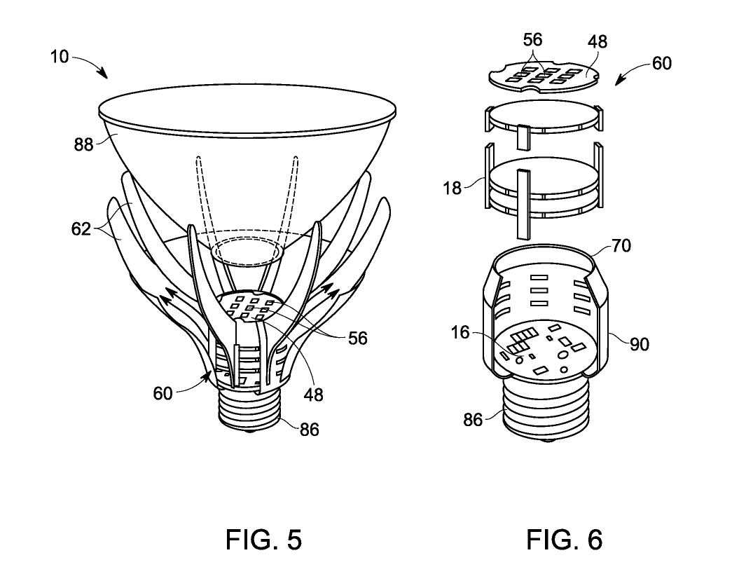

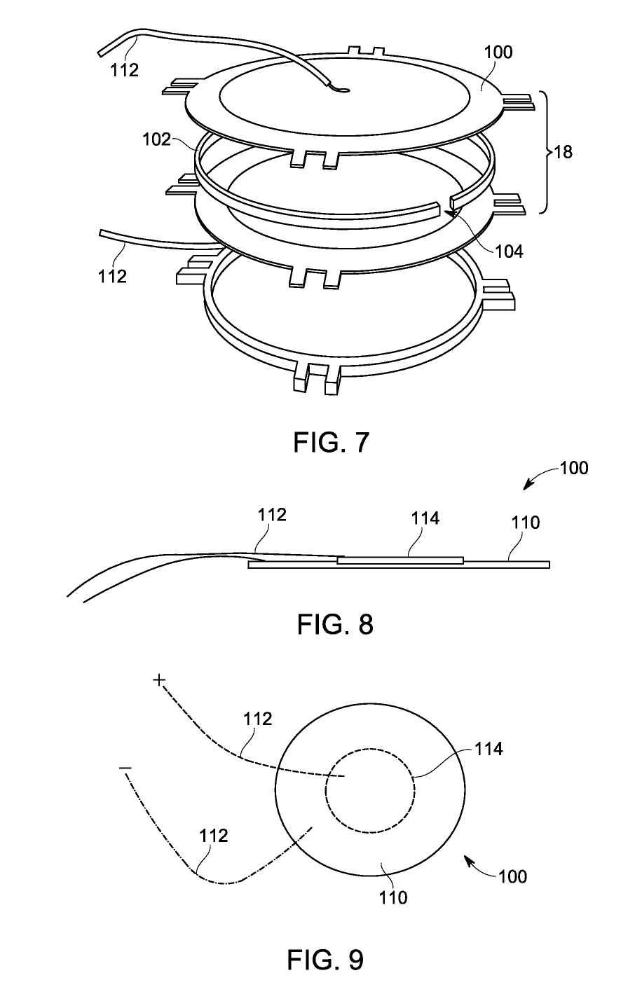

While FIGS. 2-4 depict one example of an embodiment of a lighting system 10, FIGS. 5 and 6 depict an example of an additional embodiment, with FIG. 6 depicting a partially cut-away exploded view of the lighting device 10 and FIG. 7 depicting a cut-away exploded view of the base of the lighting device, including the electronics and portions of the thermal management system.

In this example, the lighting system 10 includes a conventional screw-in base (Edison base) 86 that may be connected to a conventional socket that is coupled to the electrical power grid. A reflector 88 forms part of the housing structure for the lighting system 10 and is fitted to the system 10 so as to reflect and direct light generated by the LEDs 56. In the depicted example, a set of heat sink cooling fins 62 are positioned about the reflector 88 and allow the dissipation of heat generated by the LED electronics to the external environment.

In one implementation, heat sink cooling fins 62 are thermally coupled to a cage 90 that also forms part of the housing structure for the lighting system 10 as well as serving as part of the heat sink of the thermal management system 14. The cage 90 surrounds, in the depicted example, the power or driver electronics 16 for the LEDs 56 as well as for the synthetic jet devices 18. In accordance with the illustrated embodiment, all of the electronics configured to provide power for the LEDS 56, as well as the synthetic jet devices 18 are contained on a single printed circuit board. Thus, in accordance with the depicted implementation, the light source and the active components of the thermal management system share the same input power. In other embodiments, the respective power and driver electronics for these systems may be disposed on different boards or structures.

The cage 90 may include various ventilation slots or holes 22 through which air flows to assist in the cooling of the depicted lighting system 10. In the depicted example, the cage 90 also houses an assembly of synthetic jet devices 18, as discussed herein. The synthetic jet devices 18 facilitate the flow of air in and out of the cage 90, thereby helping to cool the heat generating components of the lighting system 10. As will be appreciated, any variety of fastening mechanisms may be included to secure the components of the lighting system 10, within the various depicted housing structures, such that the lighting system 10 is a single unit, once assembled for use.

With respect to the synthetic jet devices 18 of the thermal management system 14 described above, in certain embodiments the synthetic jet devices 18 are arranged proximate to the fins 62 of a heat sink 20. In such a configuration, each synthetic jet device 18, when operated, causes the flow of air across the faceplate and between the fins 62 to provide cooling of the LEDs 56. With respect to these synthetic jets, and turning to FIG. 7, each synthetic jet device 18 typically includes one or more diaphragms 100 which are configured to be driven by the synthetic jet power supply 26 such that the diaphragm 100 moves rapidly back and forth within a hollow frame or spacer 102 (i.e., up and down with respect to the frame 102) to create an air jet through an opening 104 in the frame 102 which may be directed through the gaps between the fins 62 of the heat sink 20. In one embodiment, the spacer is composed of elastomeric material and the wall of the spacer 102 is approximately 0.25 mm thick. In certain implementations, the spacer 102 may also include a passage or space for one or more wire 112 or flex circuits to pass through, thereby allowing an electrical connection to be made between the structures of the diaphragm 100 and the external driver circuitry.

Turning to FIGS. 8-11, in one implementation, the diaphragm 100 consists of a metal shim 110 (such as an aluminum, steel, or stainless steel plate) that is attached to a piezoelectric material 114 (such as a PZT-5A (lead zirconate titanate) material). In one example, the piezoelectric material 114 may be attached to the shim 110 using epoxy or other suitable adhesive compositions. In operation, electrical control signals, delivered by wires 112 or other conductive structures (e.g., flexible circuits), are applied to the piezoelectric material 114, which in response deforms or otherwise imparts a mechanical strain to the attached shim 110, causing flexion of the shim 110 with respect to the frame (i.e., spacer 102). The flexion of the shim 110 in turn causes the volume of an otherwise defined space to vary, and thereby causes air motion in and out of the defined space.

For example, turning back to FIG. 7, in one embodiment, a synthetic jet assembly 18 may include two diaphragms 100 as depicted in FIGS. 8 and 9 spaced apart by a frame (i.e., a spacer) 102 having an orifice or opening 104. The synchronized operation of the diaphragms 100 (i.e., flexion of the shims 110) propels air from the interior space defined by the diaphragms 100 and spacer 102 through the orifice 104. The air pushed through the orifice 104 may be directed to a part of a heat sink 20, such as a cooling fin 62, to dissipate heat conducted to the heat sink 20. In certain embodiments, the opening 104 may have a height of about 0.55 mm to about 0.75 mm and a width of about 0.55 mm to about 0.75 mm.

More particularly, in certain embodiments the opening 104 may be sized based on the displacement volume of the synthetic jet 18 (as determined by the total volume of the area bounded by a spacer 102 and upper and lower diaphragms 100. For example, in one embodiment, the ratio of the displacement volume of a synthetic jet 18 to the volume (i.e., length×width×height) of the opening 104 is ten or greater. That is, the opening 104 may be sized to such that the total displacement volume of the synthetic jet 18 is ten or more times the volume of the opening 104.

Further, with respect to the operation of the synthetic jet 18 and, particularly, the diaphragms 100 of the synthetic jet 18, the piezoelectric elements 114 are typically excited using a sinusoidal voltage applied at a particular frequency (i.e., a driving frequency). As noted above stimulation of the piezoelectric elements 114 causes deformation of the attached shims 110 and results in movement of air into and out of the space defined by the diaphragms 100 and spacer 102 through the opening 104. In practice the driving the piezoelectric elements 114 at certain frequencies can be associated with an audible noise. As a result, the driving frequency has typically been around 120 Hz to minimize the audible noise. This low frequency, however, has typically been far below the range of driving frequencies that would yield the desired degree of air flow (i.e., air displacement).

To address this issue, in certain present embodiments the piezoelectric elements 114 are operated using a driving frequency in the ultrasonic range (e.g., greater than 20 kHz or 25 kHz), outside the range of perceptible sound for humans. For example, referring to FIGS. 1 and 7, the driver electronics 16 and/or synthetic jet power supply 26 may drive the piezoelectric elements 114 of a synthetic jet 18 at the driving frequency via electrical signals transmitted using wires 112 or a flex circuit. In addition, the driving frequency may also be selected to correspond to a resonant mode of the diaphragm 100 (i.e., the driving frequency corresponds to a mechanical resonance frequency for the diaphragm 100). As a result, when driven at a mechanical resonance frequency and at an ultrasonic frequency, the operation of the diaphragms may be optimized with respect to the rate of air displacement and may be essentially noiseless (i.e., outside the human audible range).

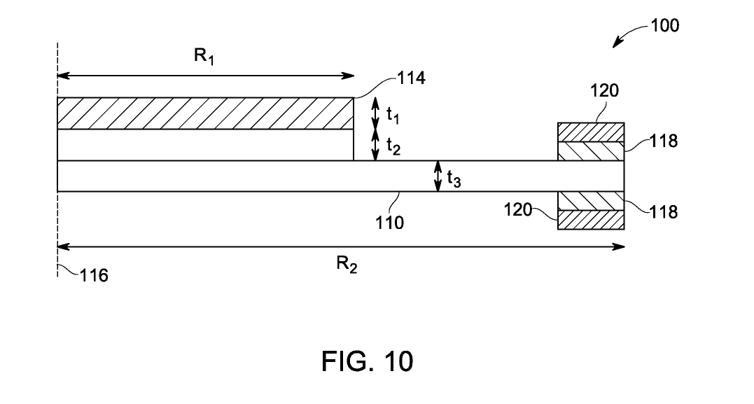

With the foregoing considerations in mind, FIG. 10 depicts an axi-symmetric representation (i.e., with respect to axis of symmetry 116) of a cross section through one embodiment of a diaphragm 100 suitable for driving at ultrasonic frequencies. In this example, the piezoelectric material 114 is mounted on a stainless steel shim that is etched on one surface to have a radius (R₁) with respect to the axis of symmetry 116 that corresponds to the radius of the piezoelectric material 114. The remainder of the shim 110, however, is not etched and has a different radius (R₂) with respect to the axis of symmetry 116. In certain implementations, the corresponding diameter of the diaphragm 100 is about or less than 25 mm, allowing a synthetic jet formed using the diaphragm 100 to fit within a conventional light socket base (e.g., and Edison base). In addition, the piezoelectric element 114 and the shim 110 have respective thickness t₁, t₂, and t₃) that help determine the operational characteristics of the diaphragm 100. As depicted in FIG. 10, an attachment material 118 (such as silicone or steel) may also be present and used to attach the shim 110 to other structures, such as the depicted stiffener 120.

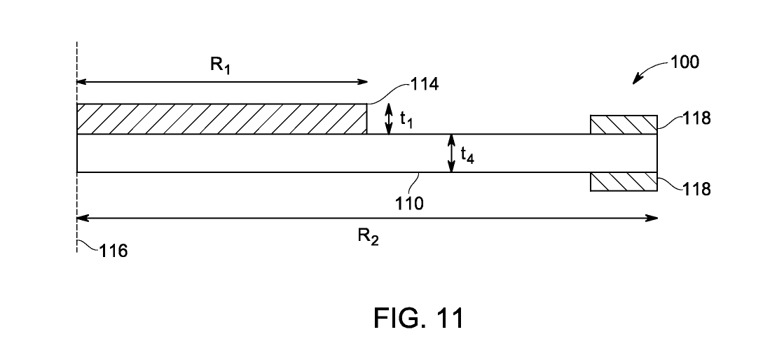

Turning to FIG. 11, in other embodiments, the shim 110 may not have an etched surface and may, thus, have only a single radius (R₂) with respect to the axis of symmetry 116. In implementations where the shim 110 is not etched, there is only a single thickness associated with the shim 110 (e.g., t₄ in the depicted example). In the depicted example, no stiffener structure 120 is employed with the un-etched shim 110, though an attachment material 118 may still be present to secure the shim 110 to a spacer 102 or other structure.

With the foregoing discussion in mind and by way of example, in certain implementations the diameter (Dₛ) of the shim 110 (i.e., 2R₂) may be in a range from about 15 mm to about 25 mm (e.g., 15 mm, 20 mm, 25 mm, and so forth) and the ratio of the diameter (Dₚ) of the piezoelectric material 114 to Dₛ (i.e., Dₚ/Dₛ) is in the range of about 0.4 to about 0.7 (e.g., 0.4, 0.55, 0.7, and so forth). In an implementation where the shim 110 is etched to have two different thicknesses (t₂ and t₃), the etched portion of the shim 110 may have a thickness, t₂, in a range of about 50 μm to about 400 μm (e.g., 50 μm, 225 μm, 400 μm, and so forth). In such an implementation the ratio of the thickness, t₁, of the piezoelectric material 114 to t₂ (i.e., t₁/t₂) may be in the range of about 0.5 to about 2 (e.g., 0.5, 1, 2, and so forth) while the ratio of the thicknesses of the etched portion of the shim 110 to the unetched portion (i.e., t₂/t₃) may be in the range of about 0.5 to about 2 (e.g., 0.5, 1, 2, and so forth). In embodiments where a stiffener 120 is present, the length of the stiffener 120 in the radial direction with respect to the shim 110 may be in the range of about 0.6 mm to about 2 mm (e.g., 0.6 mm, 1.3 mm, 2 mm, and so forth).

For example, in one implementation a synthetic jet 18 was constructed using two spaced apart diaphragms 100 having etched shims 110, where the respective diaphragms 100 had dimensions of: Dₛ=15 mm; Dₚ/Dₛ=0.7; t₂=50 μm; t₁/t₂=0.5; t₂/t₃=2; and a stiffener 120 which is present has a radial length of 0.6 mm. In this example, the shim material was aluminum and the attachment material 118 is steel. When operated at a frequency of 30,178 Hz (i.e., approximately 30 kHz) an average air displacement, Q, from the synthetic jet 18 was on the order of 2.42×10⁻⁵ m³/s.

In another example, a synthetic jet 18 was constructed using two spaced apart diaphragms having etched shims 110, where the respective diaphragms 100 had dimensions of: Dₛ=25 mm; Dₚ/Dₛ=0.7; t₂=50 μm; t₁/t₂=1; t₂/t₃=1; and a stiffener 120 which is present has a radial length of 1.3 mm. In this example, the shim material is steel and the attachment material 118 was silicone. When operated at a frequency of 28,296 Hz (i.e., approximately 28 kHz) an average air displacement, Q, from the synthetic jet 18 was on the order of 4.48×10⁻⁵ m³/s.

While the preceding examples describe implementations in which the shim 110 of the diaphragm 100 is etched, as noted above, in other embodiments (such as depicted in FIG. 11), the shim 110 is not etched and instead has a single thickness, t₄. Further, in such embodiments where the shim 110 is not etched, a stiffener 120 may be absent. In such embodiments, the dimensions of diaphragm 100 may be comparable to those noted in the examples above, with the thickness, t₄, of the un-etched shim 110 being in the range of about 50 μm to about 800 μm.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

1. A synthetic jet assembly, comprising:
a spacer comprising at least one opening through which air flows when the synthetic jet assembly is operated; and
a pair of synthetic jet diaphragms attached to opposite sides of the spacer, wherein each synthetic jet diaphragm comprises:
a deformable shim; and
a piezoelectric element attached to the deformable shim;
control circuitry configured to drive the pair of synthetic jet diaphragms at an ultrasonic frequency.

2. The synthetic jet assembly of claim 1, wherein a ratio of a volume of air displaced by the synthetic jet assembly when operated relative to a volume defined by the opening is equal to ten or greater.

3. The synthetic jet assembly of claim 1, wherein the ultrasonic frequency is equal to or greater than 20 kHz.

4. The synthetic jet assembly of claim 1, wherein the ultrasonic frequency is a mechanical resonance frequency of the synthetic jet diaphragms.

5. The synthetic jet assembly of claim 1, wherein the control circuitry comprises one or both of driver electronics or a synthetic jet power supply.

6. The synthetic jet assembly of claim 1, wherein each deformable shim has a uniform thickness throughout.

7. The synthetic jet assembly of claim 1, wherein each deformable shim is etched to have a first thickness corresponding to the etched region and a second thickness corresponding to the un-etched region.

8. An electronic device, comprising:
one or more heat generating electrical components; and
a thermal management system, comprising:
a heat sink in thermal communication with the one or more heat generating electrical components;
one or more synthetic jets, each synthetic jet comprising:
a pair of synthetic jets diaphragms; and
a spacer positioned between each pair of synthetic jet diaphragms, wherein each spacer comprises an opening through which air is expelled toward the heat sink during operation of the synthetic jet diaphragms;
a control circuit in communication with the one or more synthetic jets, wherein the control circuit is configured to drive each synthetic jet at an ultrasonic frequency.

9. The electronic device of claim 8, wherein the ultrasonic frequency is equal to or greater than 20 kHz.

10. The electronic device of claim 8, wherein a ratio of a volume of air displaced by each synthetic jet assembly when operated relative to a volume defined by the opening is equal to ten or greater.

11. The electronic device of claim 8, wherein the one or more heat generating components comprise a light source.

12. The electronic device of claim 8, wherein the heat sink comprises one or more cooling fins and wherein the respective openings are positioned so as cause air to flow over the one or more cooling fins.

13. The electronic device of claim 8, wherein the ultrasonic frequency is a mechanical resonance frequency of the synthetic jet diaphragms.

14. The electronic device of claim 8, wherein each synthetic jet diaphragm has a diameter less than 25 mm.

15. The electronic device of claim 8, wherein each synthetic jets diaphragm comprises:
a deformable shim; and a
a piezoelectric element attached to the deformable shim.

16. A method for cooling an electronic device, comprising:
driving a synthetic jet at an ultrasonic frequency such that air is expelled from the synthetic jet over a heat sink in thermal communication with a heat generating component.

17. The method of claim 16, wherein the ultrasonic frequency is equal to or greater than 20 kHz.

18. The method of claim 16, wherein the ultrasonic frequency corresponds to a resonance frequency of the synthetic jet.

19. The method of claim 16, wherein driving the synthetic jet comprises applying a sinusoidal voltage to the synthetic jet at the ultrasonic frequency.

20. The method of claim 16, wherein driving the synthetic jet comprises electrically stimulating a piezoelectric element attached to a deformable shim such that the shim deforms when the piezoelectric element is stimulated.
